(19) United States
(12) Patent Application Publication
(10) Pub. No.: US 2008/0251824 A1
(43) Pub. Date: Oct. 16, 2008

(54) Semiconductor memory device and manufacturing method thereof

(75) Inventor: Yasushi Yamazaki, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 11/882,707

(22) Filed: Aug. 3, 2007

(30) Foreign Application Priority Data
Aug. 9, 2006 (JP) 2006-216984

(51) Int. Cl. H01L 27/108; H01L 21/8242

(52) U.S. Cl. 257/296; 438/239; 257/E27.07

(57) ABSTRACT

A semiconductor memory device and a manufacturing method thereof are provided which enable cell-contact plugs to be formed at high yields and the yields of semiconductor memory devices to be improved in the manufacturing process. The semiconductor memory device includes: a semiconductor substrate; MOS transistors which are formed on a surface of the semiconductor substrate; a cell-contact plug which is made of poly-silicon film, is located between gates of the MOS transistors, and is connected to a source or a drain of one of the MOS transistors; a pad metal layer which is formed on the cell-contact plug; an interlayer dielectric film which is formed on the pad metal layer; a storage capacitor which is formed on the interlayer dielectric film; and a contact plug which is formed inside an opening which penetrates the interlayer dielectric film, and connects the storage capacitor with the pad metal layer.

### BACKGROUND OF THE INVENTION

1. Field of the Invention

The present invention relates to the structure of a semiconductor memory device and a manufacturing method thereof, and more particularly to the structure of a contact in a memory cell region in Dynamic Random Access Memory (DRAM).

Priority is claimed on Japanese Patent Application No. 2006-216984, filed on Aug. 9, 2006, the content of which is incorporated herein by reference.

2. Description of Related Art

Along with the miniaturization of memory cells such as DRAM, each of which is composed of a selection transistor and a capacitor, it has been increasingly difficult to form contacts with diffusion layers, which make junctions with the source and the drain of the transistor.

As shown in FIG. 6, a cell-contact pad method, that is, a method for forming a contact with a transistor cell (in particular, the diffusion layers) in the form of contact plugs using a poly-silicon pad, is generally used for this type of contact.

Specifically, cell-contact plugs made of poly-silicon are used to form a contact with the diffusion layers for a source 9 and a drain 10 (refer to Japanese Unexamined Patent Application, First Publication No. 2002-083881 and the like). FIGS. 6 and 8 are schematic views of the cross-sectional structure of a memory cell region. FIG. 7 is a schematic plan view of a conventional memory cell region. It should be noted that FIGS. 6 and 8 are schematic views showing the same cross section seen from an A-A′ line in FIG. 7.

Hereinafter, referencing to FIGS. 6 and 8, a conventional cell-contact pad method for forming the cell contact plugs is described in detail.

First, as shown in FIG. 6, an element isolation film 2 is formed on one of principal surfaces (the upper surface in the figure) of a semiconductor substrate 1, and after a poly-silicon film 4, a metal film 5 (any of high-melting point metals and silicide thereof, etc.), and a dielectric film 7 of SiN (silicon nitride) are sequentially formed on the surface of a channel region CH of a transistor via a gate dielectric film 3, the dielectric film 7 is etched by lithography and dry etching. Then, the metal film 5 and poly-silicon film 4 are etched using the dielectric film 7 as a mask to form a gate electrode 6.

Then, SiN is formed on the whole surface and an etch-back process is performed to form a side wall film 8 on the side walls of the gate electrode 6.

Using the gate electrode 6 and the side wall film 8 as masks, ions are implanted to form diffusion layers for the source 9 and the drain 10.

Next, a poly-silicon film 200 containing phosphorus or the like is deposited on the whole surface of the semiconductor substrate by the Chemical Vapor Deposition (CVD) method, and cell-contact plugs 12 and 13, which are connected to the source 9 and the drain 10, respectively, are formed as described below.

The deposited poly-silicon film 200 is flattened by the Chemical Mechanical Polishing (CMP) method and a resist is applied thereon.

Then, photolithography is applied using the mask for forming the cell-contact plugs to form a photo-resist pattern 100.

Next, as shown in FIG. 8, anisotropic etching is applied using the photo-resist pattern 100 as the mask, the poly-silicon film 200 is isolated for each contact, and both of the cell-contact plug 12 connected to the diffusion layer for the source 9 and the cell-contact plug 13 connected to the diffusion layer for the drain 10 are formed.

Next, an interlayer dielectric film 11 is formed on the whole surface and is flattened by the CMP method or the like to expose the surfaces of the cell-contact plugs 12 and 13.

These steps enable the cell-contact plugs to be formed for highly-miniaturized DRAM and the like, which have a large overlap margin of a contact in the memory cell with respect to the gate electrode 6 seen from the plan view.

A storage capacitor for storing data is formed on the cell-contact plug 12, while bit lines for reading out data from the storage capacitor or for writing data into the storage capacitor are formed on the cell-contact plug 13 (both not indicated in the figure).

The cell-contact plugs formed in the aforementioned manner have effects of increasing the overlap margin of the contact with respect to the gate electrode 6 and providing a structure suitable for a high-density memory cell.

However, since the cell-contact plugs have been formed in the shape of islands, the photo-resist pattern for forming the cell-contact plugs takes a dot-pattern seen from the plan view as shown in FIG. 7, with a columnar cross-section as shown in FIG. 9.

For this reason, as with miniaturization-oriented design rule, such a problem may occur that the photo-resist pattern is easy to collapse in any of photo-resist wet processes such as development and rinse, disturbing the formation of a micro dot-pattern because the aspect ratio (i.e., height-width ratio) of the dot-pattern inevitably becomes larger.

Thus, as shown in FIG. 9, the conventional method for forming cell-contact plugs involves problems such as the easily collapsing or peeling off of the photo-resist pattern (refer to the leftmost photo-resist pattern 100 of FIG. 9), and the like, reducing the manufacturing yield of semiconductor memory devices.

### SUMMARY OF THE INVENTION

The present invention has been made in view of this background, and an object of the present invention is to provide a semiconductor memory device and a manufacturing method thereof, the semiconductor memory device having a structure, which enables the cell-contact plugs to be formed at high yields and the yields of semiconductor memory devices to be improved in the manufacturing process.

A semiconductor memory device according to the present invention comprises: a semiconductor substrate; MOS transistors which are formed on a surface of the semiconductor substrate; a cell-contact plug which is made of poly-silicon film, is located between gates of the MOS transistors, and is connected to a source or a drain of one of the MOS transistors; a pad metal layer which is formed on the cell-contact plug; an interlayer dielectric film which is formed on the pad metal layer; a storage capacitor which is formed on the interlayer dielectric film; and a contact plug which is formed inside an opening which penetrates the interlayer dielectric film, and connects the storage capacitor with the pad metal layer.

In the semiconductor memory device according to the present invention, the pad metal layer may have a laminar structure of tungsten, titanium nitride, and titanium layers.

In the semiconductor memory device according to the present invention, the contact plug may be made of a metal layer.

A method for manufacturing a semiconductor memory device according to the present invention comprises: a step of forming MOS transistors on a semiconductor substrate; a step of depositing a poly-silicon film and flattening a surface of the poly-silicon film, the poly-silicon film becoming a cell-contact plug which is located between gate electrodes of adjacent MOS transistors and is connected to a source or a drain of one of the MOS transistors; a step of forming a pad metal layer made of a metal layer on the poly-silicon film; and a step of etching the poly-silicon film to form the cell-contact plug using the pad metal layer as a mask.

In the method according to the present invention, the step of forming the pad metal layer may comprise: a step of forming a dielectric film on the poly-silicon film; a step of etching a region in which the cell-contact plug is formed, from the dielectric film to form an opening; a step of forming a metal film on a whole surface; and a step of flattening the metal film with only the metal film inside the opening being left, to form the pad metal layer.

In the method according to the present invention, the pad metal layer may have a laminar structure of tungsten, titanium nitride, and titanium layers.

In the method according to the present invention, after the step of etching the poly-silicon film to form the cell-contact plug, may further comprise: a step of forming a first interlayer dielectric film on the whole surface and flattening a surface of the first interlayer dielectric film to expose a surface of the pad metal layer; a step of forming a second inter-layer dielectric film on the pad metal layer and the first interlayer dielectric film; a step of forming an opening penetrating the second interlayer dielectric film to the surface of the pad metal layer; a step of forming a contact-plug inside the opening; and a step of forming a storage capacitor on the second interlayer dielectric film, the storage capacitor being connected to the contact plug.

In the method according to the present invention, the contact plug may be made of any of given metal materials.

In the method according to the present invention, the step of etching the region to form the opening may comprise: a step of forming a photo-resist pattern using a mask for removing the region in which the cell-contact plug is formed from the dielectric film; a step of removing the dielectric film by etching from the region in which the cell-contact plug is formed, to form the opening; and a step of removing the photo-resist pattern.

In the method according to the present invention, the photo-resist pattern may be honeycomb-shaped.

According to the present invention, an opening having the same shape as that of the cell-contact plug is formed in a dielectric film which is formed on a poly-silicon film, a pad metal layer is formed in the opening, and the poly-silicon film is etched to form the cell-contact plug using this pad metal layer as a mask. In this way, the present invention is different from the conventional method in which a dot photo-resist pattern is formed and anisotropically etched to form the cell-contact plug. The use of a honeycomb photo-resist pattern instead of the dot photo-resist pattern prevents the photo-resist pattern from collapsing or peeling off, and thereby the yields of cell-contact plug formation can be improved, achieving a stable yield in the manufacturing process of semiconductor devices.

Moreover, according to the present invention, the pad metal layer is formed on the cell-contact plug made of the poly-silicon film, and the pad metal layer is formed by a laminated structure of three layers; tungsten, titanium nitride, and titanium. The bottom titanium layer forms a titanium silicide with the poly-silicon film to reduce contact resistance, and the middle titanium nitride layer serves as a barrier to prevent the tungsten layer from reacting with the poly-silicon film. Accordingly, it is possible that the pad metal layer is used as a buffer layer and the metal contact-plug is formed on the cell-contact plug made of poly-silicon. The use of the metal contact plug can reduce (to about ⅕) a series resistance in the wiring up to a storage capacitor for data storage compared with the use of the conventional poly-silicon film for the contact plug.

### BRIEF DESCRIPTION OF THE DRAWINGS

FIG. 1 is a schematic view showing the cross-sectional structure of a semiconductor memory device according to one embodiment of the present invention.

FIG. 2 is a schematic view showing the plane structure of a semiconductor memory device according to one embodiment of the present invention.

FIGS. 3 through 5 are schematic views showing the cross-sectional structures in the manufacturing processes of the semiconductor memory device shown in FIG. 1.

FIG. 6 is a schematic view showing the cross-sectional structure of a semiconductor memory device fabricated by the conventional cell-contact pad method.

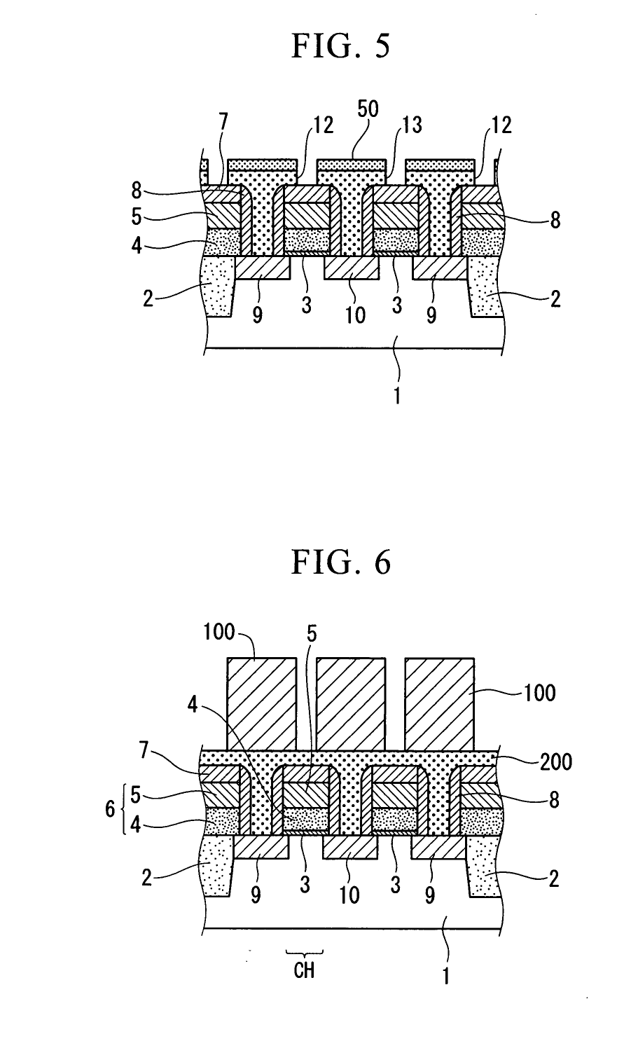

FIG. 7 is a schematic view showing the plane structure of the semiconductor memory device fabricated by the conventional cell-contact pad method.

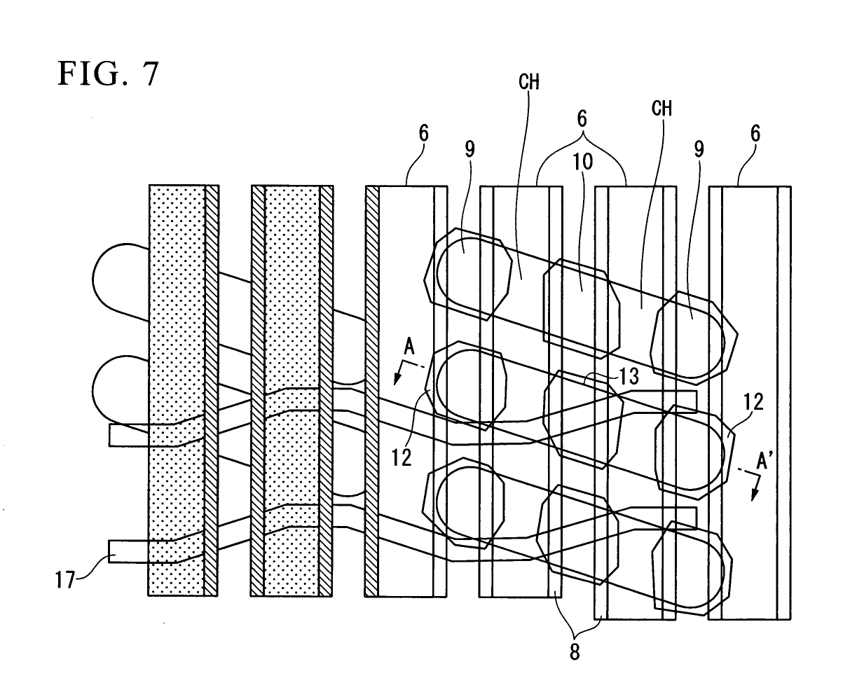

FIGS. 8 and 9 are schematic views showing the cross-sectional structures of the semiconductor memory device fabricated by the conventional cell-contact pad method.

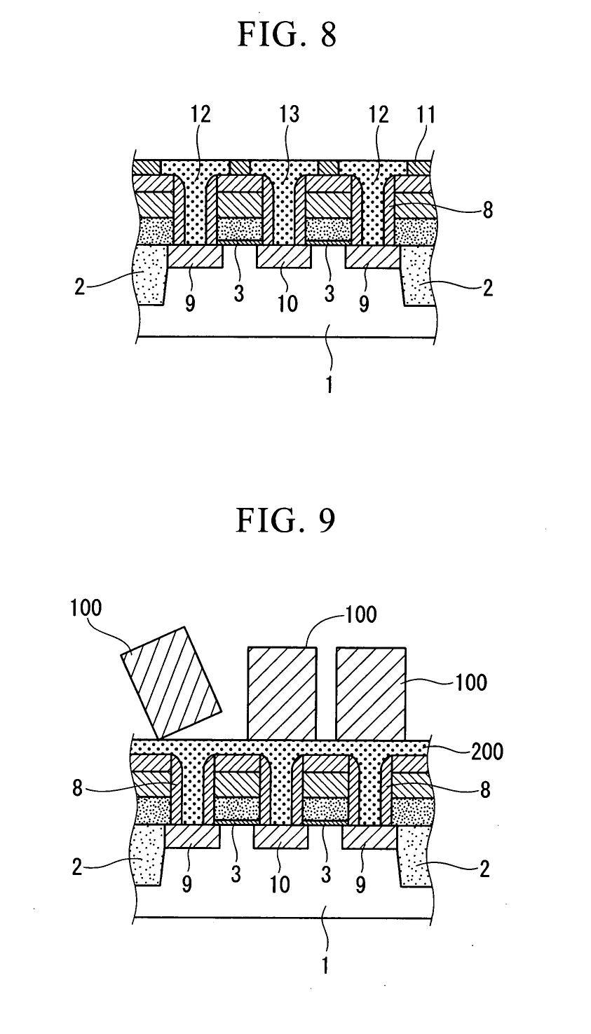

### DETAILED DESCRIPTION OF THE INVENTION

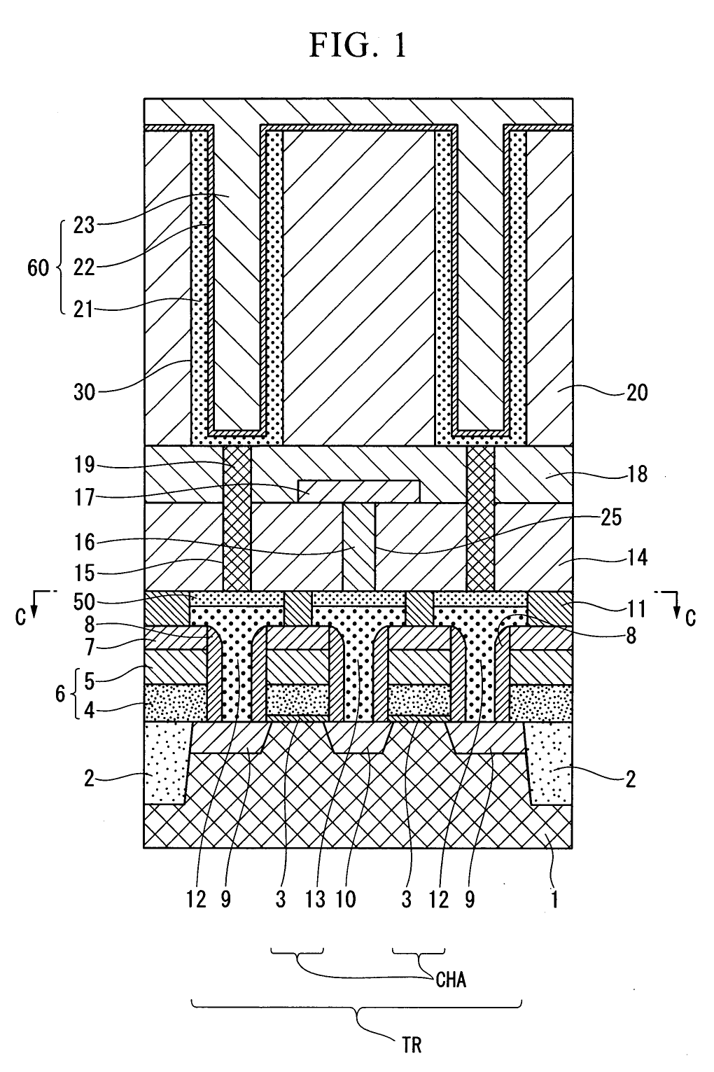

Hereinafter, referring to the accompanying drawings, the semiconductor memory device according to one embodiment of the present invention is described in detail. FIG. 1 is a schematic view showing the cross-sectional structure of the semiconductor memory device according to the present embodiment.

In this figure, a semiconductor substrate 1 is made of a semiconductor material containing given concentrations of impurities, for example silicon.

An element isolation region 2 is formed in a surface region of the semiconductor substrate 1 excluding a transistor formation region TR by the Shallow Trench Isolation (STI) method to isolate between transistors (i.e., selection transistors such as Metal Oxide Semiconductors (MOS) transistors).

In the transistor formation region TR, a gate dielectric film 3 is formed on the surface of the semiconductor substrate 1 as a silicon oxide film through thermal oxidization or the like. A gate electrode 6 is made of a multilayer film of a poly-silicon film 4 and a metal film 5. The poly-silicon film 4 may be a doped poly-silicon film, which is formed by doping impurities in the silicon film material during deposition by the CVD method. The metal film 5 may be made of any of high-melting point metals such as tungsten (W) and tungsten silicide (WSi).

A dielectric film 7 made of silicon nitride (SiN) or the like is formed on the gate electrode 6, in particular on the metal film 5. A side wall film 8, which is dielectric film made of SiN or the like, is formed on the side walls of the gate electrode 6.

A diffusion layer for the source 9 is formed on the surface region of the semiconductor substrate 1 at one end of the gate electrode 6, while a diffusion layer for the drain 10 is formed at the other end of the gate electrode 6. It should be noted that the reference symbol “CHA” in the figure indicates a channel formation region.

A cell-contact plug 12 connected to the diffusion layer for the source 9 and a cell-contact plug 13 connected to the diffusion layer for the drain 10, which are made of poly-silicon films containing given concentrations of impurities, are formed in contact holes associated with them, the contact holes being formed in a self-aligned manner by means of the dielectric film 7 and the side wall film 8. The cell-contact plugs indicate the contact plugs to be connected to the diffusion layers for the source and drain of the transistor.

The top surfaces of the cell-contact plugs 12 and 13 are formed so that they project over the top of the gate electrode 6 higher than the side of the gate electrode 6, the top surfaces having an exposed surface area larger than those of the areas, which are in contact with the diffusion layers for the source 9 and the drain 10.

A pad metal layer 50 is formed on the top surfaces of the cell-contact plugs 12 and 13, the pad metal layer 50 being made of the multilayer film of the tungsten, titanium nitride, and titanium layers.

A first interlayer dielectric film 11 is formed in a groove formed between the cell-contact plugs 12 and 13. Specifically, the cell-contact plugs 12 and 13 are electrically isolated from their adjacent cell-contact plugs by means of the first interlayer dielectric film 11, and the top surface of the pad metal layer 50 exposes from the first interlayer dielectric film 11.

A second interlayer dielectric film 14 is formed on the pad metal layer 50 and the first interlayer dielectric film 11 so that it covers the whole surface of the pad metal layer 50 and the first interlayer dielectric film 11.

A contact hole 25 is formed by penetrating the second interlayer film 14 so as to expose the pad metal layer 50 on the cell-contact plug 13.

A contact plug 16 made of a metal material such as a multilayer film of titanium, titanium nitride, and tungsten layers is formed inside the contact hole 25.

A bit wiring layer 17 composed of any of the metal films such as the tungsten film is formed on a surface of the contact-plug 16. Specifically, the bit wiring layer 17 is connected to the diffusion layer of the drain 10 via the contact plug 16, the pad metal layer 50, and the cell-contact plug 13.

A third interlayer dielectric film 18 is formed on the bit wiring layer 17 and the second interlayer dielectric film 14.

A contact hole 15 is formed by penetrating the second and third interlayer dielectric films 14, 18 so as to expose the surface of the pad metal layer 50 on the top surface of the cell-contact plug 12.

A contact plug 19 made of metal materials such as a multilayer film of titanium, titanium nitride, and tungsten layers is formed inside the contact hole 15.

A fourth interlayer dielectric film 20 is formed on the exposed surface of the contact plug 19 and the third interlayer dielectric film 18. Each of the first, second, third, and fourth interlayer dielectric films 11, 14, 18, and 20 is composed of a silicon oxide film, a phospho-silicate glass (PSG), or a borophospho-silicate glass (BPSG).

The fourth interlayer dielectric film 20 penetrates to form an opening 30 for forming a capacitor storage 60 in the area where a surface of the contact plug 19 is exposed.

A lower electrode 21 made of any of metal materials with a given thickness is formed on the inner peripheral surface of the opening 30 so as to connect to the contact plug 19.

A capacitor dielectric film 22 with a given thickness is formed on the fourth interlayer dielectric film 20 and the surface of the lower electrode 21.

An upper electrode 23 is formed on the capacitor dielectric film 22. Specifically, a capacitor composed of the lower electrode 21, the capacitor dielectric film 22, and the upper electrode 23, is formed which serves as the capacitor storage 60 for storing data.

Now, referring to FIGS. 1 to 5, a method for manufacturing the semiconductor memory device according to the present embodiment is described in detail. In the following explanation, the method for fabricating, in particular, DRAM memory cell region is described. It should be noted that the method for fabricating a peripheral circuit region is omitted because of being the same as that of transistors in the memory cell region.

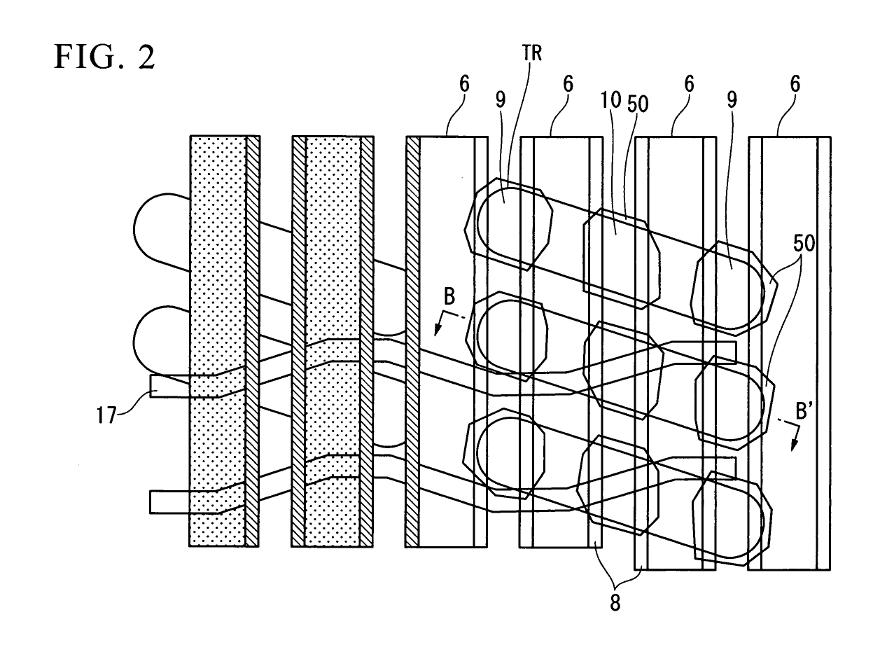

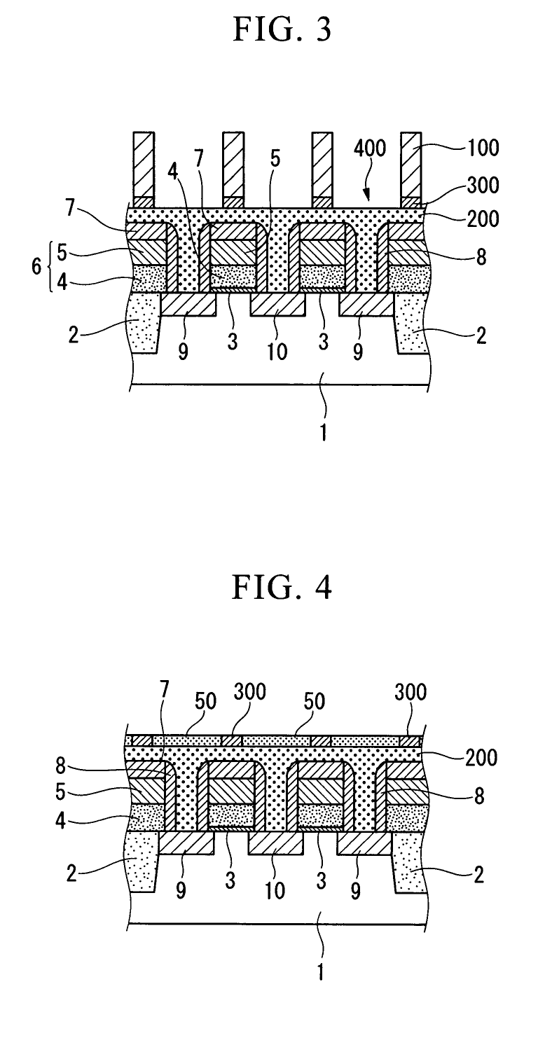

FIG. 2 is a schematic view showing the plane structure of the semiconductor memory device in layers (including the bit-wiring layer) in the part lower than a C-C line shown in FIG. 1, in which the capacitor storage 60 is not shown in order to definitively explain the fundamental parts of the present embodiment. FIGS. 3 to 5 are schematic views mainly explaining the main manufacturing steps of the present invention and showing the cross-sectional structure of the semiconductor memory device seen from a B-B′ line shown in FIG. 2 (the same as that in FIG. 1).

For example, as shown in FIG. 3, in order to segment transistor formation regions TR on the principal surface of the semiconductor substrate 1 made of a P-type single-crystal silicon material, an element isolation film 2 is formed by the STI method over all the regions of the principal surface of the semiconductor substrate 1 excluding the transistor formation regions TR.

Then, the surface of the semiconductor substrate 1 is oxidized to form a silicon oxide film by thermal oxidization, thereby forming a gate dielectric film 3 of 4 nm in thickness in the transistor formation region TR.

Next, a poly-silicon film 4 of 70 nm in thickness containing an N-type impurity is formed on the gate dielectric film 3 by the CVD method using mono-silane (SiH₄) and phosfin (PH₃) as raw material gases.

Next, a 50 nm-thickness film, which is made of any of high-melting point metals such as tungsten, tungsten nitride, and tungsten silicide, is deposited as the metal film 5 on the poly-silicon film 4 by sputtering.

Next, a 70 nm-thickness dielectric film 7, which is made of a silicon nitride, is deposited on the metal film 5 by the plasma CVD method using mono-silane and ammonia (NH₃) as raw material gases.

Next, a resist material is applied onto the dielectric film 7, and photolithography is performed using a mask for the formation of the gate electrode 6 to form the photo-resist pattern for the formation of the gate electrode 6.

The photo-resist pattern is used in anisotropic etching as the mask to etch the dielectric film 7. After the photo-resist pattern has been removed, the metal film 5 and the poly-silicon film 4 are etched using the dielectric film 7 as the mask to form the gate electrode 6.

Next, the silicon nitride film of 40 nm in thickness is deposited on the whole surface by the CVD method, and an etch-back process is performed to form the side wall film 8.

Any of N-type impurities (for example, arsenic (As)) of 5×10¹² to 1×10¹³ cm⁻² is ion-implanted at 15 to 30 eV of implanting energy using the gate electrode 6 and the side wall film 8 as the masks, and then annealed in the nitrogen atmosphere at a temperature of 900 to 1000 Celsius degree for one minute to form the diffusion layers for the source 9 and the drain 10. Alternatively, ion-implantation may be done to form the diffusion layers for the source 9 and the drain 10 under the aforementioned conditions before the side wall film 8 is formed.

After forming the transistor structure in the transistor formation region TR as described above, a poly-silicon film 200 of 300 nm in thickness is deposited by the CVD method as in the poly-silicon film 4, and is flattened to about 250 nm in thickness from the surface of the semiconductor substrate 1 by the CMP method.

Next, a mask dielectric film 300 of 250 to 300 nm in thickness, which is made of, for example, a silicon oxide film, is deposited on the poly-silicon film 200 by the plasma CVD method.

Then, a photo-resist material of 300 nm in thickness is applied onto the mask dielectric film 300, and a photo-resist pattern 100 is formed by photolithography using a mask for removing the mask dielectric film 300 from the cell-contact plug regions.

Then, unlike the conventional columnar photo-resist pattern, a pattern with holes, namely a honeycomb photo-resist pattern 100 is formed. Accordingly, the photo-resist pattern constructed into a network is subjected to the influence of the aspect ratio less than the conventional columnar photo-resist pattern, preventing the photo-resist pattern from collapsing or peeling off in the photo-resist wet processes such as development and rinse.

Next, the mask dielectric film 300 is removed from the cell-contact plug formation region, namely the region, in which the pad metal layer 50 shown in FIG. 2 is formed, by anisotropic etching to form an opening 400 of the same shape as that of the pad metal layer 50 seen from the plan view, the pad metal layer 50 being formed on the top surface of the cell-contact plugs.

As shown in FIG. 4, the pad metal layer 50 is formed inside the opening 400 by following the steps of: removing the photo-resist pattern 100; sequentially depositing a titanium (Ti) of 10 nm in thickness, a titanium nitride (TiN) of 40 nm in thickness, and a tungsten (W) of 250 nm in thickness on the whole surface including the exposed poly-silicon film 200 by sputtering; flattening the top surface of the deposited laminar layer by the CMP method; and removing the W, TiN, and Ti layers excluding those at the opening 400.

Next, as shown in FIG. 5, the mask insulating layer 300 and the poly-silicon film 200 positioned directly beneath it seen from a plan view are anisotropically etched using the pad metal layer 50 as the mask using HBr (or HCl)+H₂ (or He) as etching gases.

As a result, as shown in FIG. 5, the cell-contact plugs 12 and 13, as well as the pad metal 50 on the top surfaces thereof are formed.

Next, as shown in FIG. 1, a first interlayer dielectric film 11 of 450 nm in thickness is formed on the whole surface by the plasma CVD method using, for example, a silicon oxide film. Then, the first interlayer dielectric film 11 is flattened by the CMP method to expose a surface of the pad metal layer 50.

Next, a second interlayer dielectric film 14 of 300 nm in thickness, which is made of a silicone oxide film, is formed on the whole surface by the plasma CVD method. Then, the photo-resist material is applied thereon. The photo-resist pattern is formed by photolithography using the mask to form the contact hole for connecting the cell-contact plug 13 to the bit wiring layer 17, and anisotropic etching is performed using the photo-resist pattern as the mask. This anisotropic etching step forms a contact hole 25, which penetrates the second interlayer dielectric film 14 until it faces directly the exposed pad metal layer 50 on the cell-contact plug 13. It should be noted that the step of forming the first interlayer dielectric film 11 may be omitted and instead, the second interlayer dielectric film 14 may be used. In this case, after the formation of the second interlayer dielectric film 14, the surface is flattened by the CMP method.

After the removal of the photo-resist, the metal film, which forms a contact plug 16, is deposited by the CVD method on the whole surface including the contact hole 25, and the film surface is flattened by the CMP method to form the contact plug 16 with the top surface thereof exposed from the contact hole 25.

Then, the metal film is formed on the whole surface, the photo-resist material is applied on the metal film, and the photo-resist pattern is formed by lithography using the mask for forming the bit wiring layer 17. The bit wiring layer 17, which connects to the contact plug 16, is formed by anisotropic etching using the photo-resist pattern as the mask.

After the removal of the photo-resist, a third interlayer dielectric film 18 of 500 nm in thickness is deposited on the whole surface by the plasma CVD method using, for example, a silicon oxide film, and then flattened by the CMP method.

Next, the photo-resist material is applied on the interlayer dielectric film 18, and the photo-resist pattern is formed by lithography using the mask to form the contact hole for connecting the cell-contact plug 12 and the lower electrode of the storage capacitor 60. Then, the contact hole 15 is formed by anisotropic etching using the photo-resist pattern as the mask, the contact hole 15 penetrating the second interlayer dielectric film 14 and the third interlayer dielectric film 18 and facing directly the exposed pad metal layer 50 on the cell-contact-plug 12.

After the removal of the photo-resist, a contact plug 19 with its upper surface exposed from the contact hole 15 is formed by the steps of: depositing the metal layer by the CVD method on the whole surface including the inside of the contact hole 15 for forming the contact plug 19; and flattening by the CMP method.

Next, a fourth interlayer dielectric film 20 of 3000 nm in thickness is formed on the whole surface by the plasma CVD method using, for example, a silicon oxide film, and flattened by the CMP method.

The photo-resist material is applied on the fourth interlayer dielectric film 20, and the photo-resist pattern is formed by photolithography using the mask to form the opening for forming the storage capacitor 60. Then, an opening 30 is formed by anisotropic etching using the thus formed photo-resist pattern as the mask, the opening 30 penetrating the fourth interlayer dielectric film 20 and facing directly the exposed top surface of the contact plug 19.

After the removal of the photo-resist, any metal material of 30 nm in thickness, for example titanium nitride, is deposited as the metal layer by the CVD method.

Then, the photo-resist material is applied, the photo-resist material excluding inside the opening 30 is removed, and then the metal layer excluding the opening 30, namely the metal layer on the surface of the fourth interlayer dielectric film 20, is removed by etching. Then, the photo-resist is removed to form a cup-shaped lower electrode 21 in the capacitor of the capacitor storage 60.

Next, a capacitor dielectric film 22 of 6 nm in thickness, which is made of aluminum oxide, is formed on the whole surface by the Atomic Layer Deposition (ALD) method.

The metal layer of 30 nm in thickness, which is made of a titanium nitride film, is formed on the capacitor dielectric film 22 by the CVD method as in the lower electrode 21. An additional metal layer may be formed on this metal layer.

An upper electrode 23 is formed by following the steps of: applying the photo-resist material onto the metal layer; forming the photo-resist pattern to fabricate the upper electrode 23 using the mask having the shape of the upper electrode 23; and etching the photo-resist material using the photo-resist pattern as the mask.

As a result, the capacitor storage 60 composed of the lower electrode 21, the capacitor dielectric film 22, and the upper electrode 23 is formed, the lower electrode 21 being connected to the contact plug 19.

By following the aforementioned steps, the memory cell region of the semiconductor memory device according to the present embodiment is formed. A peripheral circuit region, in which data is written into and read out of the capacitor storage 60 in the memory cell region, can be formed by following the aforementioned steps.

While preferred embodiments of the present invention have been described and illustrated above, it should be understood that these are exemplary of the present invention and are not to be considered as limiting. Additions, omissions, substitutions, and other modifications can be made without departing from the scope of the present invention. Accordingly, the present invention is not to be considered as being limited by the foregoing description, and is only limited by the scope of the appended claims.

What is claimed is:

1. A semiconductor memory device comprising:
a semiconductor substrate;
MOS transistors which are formed on a surface of the semiconductor substrate;
a cell-contact plug which is made of poly-silicon film, is located between gates of the MOS transistors, and is connected to a source or a drain of one of the MOS transistors;
a pad metal layer which is formed on the cell-contact plug;
an interlayer dielectric film which is formed on the pad metal layer;
a storage capacitor which is formed on the interlayer dielectric film; and
a contact plug which is formed inside an opening which penetrates the interlayer dielectric film, and connects the storage capacitor with the pad metal layer.

2. The semiconductor memory device according to claim 1, wherein the pad metal layer has a laminar structure of tungsten, titanium nitride, and titanium layers.

3. The semiconductor memory device according to claim 2, wherein the contact plug is made of a metal layer.

4. A method for manufacturing a semiconductor memory device comprising:
a step of forming MOS transistors on a semiconductor substrate;
a step of depositing a poly-silicon film and flattening a surface of the poly-silicon film, the poly-silicon film becoming a cell-contact plug which is located between gate electrodes of adjacent MOS transistors and is connected to a source or a drain of one of the MOS transistors;
a step of forming a pad metal layer made of a metal layer on the poly-silicon film; and
a step of etching the poly-silicon film to form the cell-contact plug using the pad metal layer as a mask.

5. The method according to claim 4, wherein the step of forming the pad metal layer comprises:
a step of forming a dielectric film on the poly-silicon film;
a step of etching a region in which the cell-contact plug is formed, from the dielectric film to form an opening;
a step of forming a metal film on a whole surface; and
a step of flattening the metal film with only the metal film inside the opening being left, to form the pad metal layer.

6. The method according to claim 4, wherein the pad metal layer has a laminar structure of tungsten, titanium nitride, and titanium layers.

7. The method according to claim 4, after the step of etching the poly-silicon film to form the cell-contact plug, further comprising:
a step of forming a first interlayer dielectric film on the whole surface and flattening a surface of the first interlayer dielectric film to expose a surface of the pad metal layer;
a step of forming a second inter-layer dielectric film on the pad metal layer and the first interlayer dielectric film;
a step of forming an opening penetrating the second interlayer dielectric film to the surface of the pad metal layer;
a step of forming a contact-plug inside the opening; and
a step of forming a storage capacitor on the second interlayer dielectric film, the storage capacitor being connected to the contact plug.

8. The method according to claim 7, wherein the contact plug is made of any of given metal materials.

9. The method according to claim 5, wherein the step of etching the region to form the opening comprises:
a step of forming a photo-resist pattern using a mask for removing the region in which the cell-contact plug is formed from the dielectric film;
a step of removing the dielectric film by etching from the region in which the cell-contact plug is formed, to form the opening; and
a step of removing the photo-resist pattern.

10. The method according to claim 9, wherein the photo-resist pattern is honeycomb-shaped.
